(19) United States
(12) Patent Application Publication
(10) Pub. No.: US 2014/0238849 A1
(43) Pub. Date: Aug. 28, 2014

(54) METHODS AND APPARATUS FOR CONTROLLING DOPANT CONCENTRATION IN THIN FILMS FORMED VIA SPUTTERING DEPOSITION

(71) Applicant: First Solar, Inc., Tempe, AZ (US)

(72) Inventors: Scott Daniel Feldman-Peabody, Golden, CO (US); Stacy Ann Black, Longmont, CO (US); Robert Dwayne Gossman, Aurora, CO (US); Patrick Lynch O'Keefe, Loveland, CO (US)

(73) Assignee: First Solar, Inc., Tempe, AZ (US)

(21) Appl. No.: 13/775,613

(22) Filed: Feb. 25, 2013

(51) Int. Cl. C23C 14/34; C23C 14/56

(52) U.S. Cl. CPC C23C 14/3407; C23C 14/56
USPC 204/298.08; 204/298.23; 204/298.11; 204/298.12; 204/298.13; 204/298.26; 427/299

(57) ABSTRACT

Sputtering chambers including one or more first sputtering targets within the sputtering chamber and one or more second sputtering targets are generally provided. Each first sputtering target comprises a source material, and each second sputtering target comprises the source material and a dopant. A conveyor system is configured to transport a plurality of substrates through the sputtering chamber to deposit a thin film onto a surface of each substrate. A power source is electrically connected to each of the first sputtering targets and the second sputtering target. A target shield can also be included within the sputtering chamber, and can be positioned between a portion of the second sputtering target and the conveyor system. The dopant can be present within the second sputtering target as a discrete insert within a cavity defined by the source material. Methods are also provided for making a sputtering target and depositing a thin film.

### FIELD OF THE INVENTION

The subject matter disclosed herein relates generally to forming a sputtering deposition methods and apparatus. More particularly, the subject matter disclosed herein relates to sputtering deposition methods and apparatus of forming a thin film layer having a controlled dopant concentration.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials. The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type absorber layer (i.e., an electron accepting layer) and the CdS layer acts as a n-type window layer (i.e., an electron donating layer). A transparent conductive oxide (“TCO”) layer is commonly used between the window substrate (e.g., glass) and the junction forming layers. A resistive transparent buffer (“RTB”) layer can be present between the TCO layer and the n-type window layer to allow for a relatively thin n-type window layer to be formed to help minimize shunts and other deficiencies between the absorber layer and the TCO layer.

In many manufacturing processes of such PV modules, sputtering deposition is utilized to form at least one of the thin film layers. For example, sputtering deposition can be particularly useful to from the TCO layer, RTB layer, CdS layer, etc. However, controlling a dopant concentration in a thin film formed via sputtering deposition is particularly difficult, especially at very low dopant concentrations.

Often, sputter targets are manufactured with dopants mixed into the matrix of the sputtering material. In some cases, however, it is desirable to have an extremely low concentration of a dopant (e.g., about 10 ppm or less). For example, it may be desirable to include copper (as a dopant) in a zinc-tin oxide layer (ZTO) serving as a RTB layer in a PV module. However, it is very difficult to reproducibly manufacture targets doped to such a low concentration.

Thus, a need exists for a thin film layer formed via sputtering with controlled stoichiometry, particularly with respect to the dopant concentration, in order to produce a more optimized and stabilized PV thin film device.

### BRIEF DESCRIPTION OF THE INVENTION

Aspects and advantages of the invention will be set forth in part in the following description, or may be obvious from the description, or may be learned through practice of the invention.

Sputtering chambers are generally provided that include, in one embodiment, a first sputtering target within the sputtering chamber and a second sputtering target within the sputtering chamber. The first sputtering target comprises a source material, and the second sputtering target comprises the source material and a dopant. A conveyor system is configured to transport a plurality of substrates through the sputtering chamber to deposit a thin film onto a surface of each substrate.

In one embodiment, the sputtering chamber includes a plurality of the first sputtering targets within the sputtering chamber. Each of the first sputtering targets can be substantially free from the dopant.

A power source is electrically connected to the sputtering chamber and to each of the first sputtering targets and the second sputtering target. In one embodiment, the power supply is individually connected to each of the first sputtering targets and the second sputtering target. For example, the power source can include a plurality of power supplies, with a power supply individually connected to each of the first sputtering targets and the second sputtering target. As such, the power supply can be configured to provide a first power level to each of the first sputtering targets and a second power level to the second sputtering target (e.g., the second power level can be less than the first power level).

A target shield can also be included within the sputtering chamber, and can be positioned between a portion of the second sputtering target and the conveyor system. For example, the target shield can extend over at least a portion of the second sputtering target (e.g., over about 25% to about 75% of the second sputtering target) and/or over at least a portion of each of the first sputtering targets.

The dopant can be, in particular embodiments, present within the second sputtering target as a discrete insert within a cavity defined by the source material.

Methods are also generally provided for making a sputtering target. In one embodiment of the method, a source material is pressed to form the sputtering target, an aperture is then formed within the sputtering target, and finally the aperture is filled with a dopant.

Sputtering targets are also generally provided, which in one embodiment, include a source material and a dopant. The source material generally defines a cavity extending in a direction perpendicular to the sputtering surface of the sputtering target. The dopant is present within the cavity. For example, the sputtering target can define a length that is perpendicular to the sputtering surface defined by the sputtering target, with the cavity defining a slot extending across about 75% or more of the length of the sputtering target. The sputtering target can define a plurality of cavities within the sputtering target, each cavity extending perpendicular to the sputtering surface, and wherein the dopant is present within each cavity. In one particular embodiment, the source material comprises zinc and tin, and wherein the dopant comprises copper.

Methods are also generally provided for sputtering multiple targets in a sputtering chamber to deposit a thin film on a substrate. In one embodiment, the method includes: forming a plasma in the sputtering chamber between the targets and the substrate such that atoms are ejected from the targets, and depositing the atoms ejected from the first targets and the second target onto the substrate to form the thin film. The sputtering chamber comprises a plurality of first sputtering targets and a second sputtering target. Each first sputtering target comprises a source material, and the second sputtering target comprises the source material and a dopant such that the thin film comprises the source material and the dopant.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a cross-sectional view of an exemplary DC sputtering chamber according to one embodiment of the present invention;

FIG. 2 shows a side view of a plurality of first sputtering targets and a second sputtering target for use in a sputtering chamber, such as the exemplary DC sputtering chamber of FIG. 1;

FIG. 3 shows a cross-sectional top view of a shielded sputtering target according to one embodiment of the exemplary DC sputtering chamber of FIG. 1;

FIG. 4 shows a cross-sectional top view of an exemplary doped sputtering target;

FIG. 5 shows a cross-sectional side view of the exemplary doped sputtering target of FIG. 4;

FIG. 6 shows a general schematic of a cross-sectional view of an exemplary cadmium telluride thin film photovoltaic device according to one embodiment of the present invention; and,

FIG. 7 shows a side view of a plurality of first sputtering targets and a second sputtering target for use in a sputtering chamber, such as the exemplary DC sputtering chamber of FIG. 1.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise stated. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Sputtering apparatus and methods are generally provided, along with doped sputtering targets for use therein. In one embodiment, the sputtering apparatus and methods can be particularly useful for forming a resistive transparent buffer (“RTB”) layer on a substrate during the manufacture of a PV device. However, the sputtering apparatus and methods can be utilized to form any thin film layer (e.g., the TCO layer, the n-type window layer, the p-type layer, etc) that is desired to be formed via sputtering deposition.

For example, the RTB layer can be deposited via sputtering deposition on a transparent conductive oxide layer on a transparent substrate (i.e., a “superstrate”). In one embodiment, the RTB layer can generally include a copper doped tin oxide. In certain embodiments, the RTB layer can further include zinc (e.g., a copper doped zinc-tin oxide). Without being bound to any particular theory, it is believed that the presence of copper in the RTB layer serves to dope the absorber layer (e.g., a cadmium telluride layer) in the finished PV device as the copper will diffuse from the RTB layer into the absorber layer (through any intermediate layers present in the film stack) during the high-temperatures to which the substrate is exposed in subsequent processing steps.

In one particular embodiment, the RTB layer can include a copper and zinc doped tin oxide (i.e., a zinc-tin oxide). For instance, zinc can be present in the RTB layer in an atomic amount up to 7.5 atomic %, such as about 0.1 atomic % to about 5 atomic %. In one embodiment, for instance, zinc can be present in the RTB layer in an atomic amount of about 0.1 atomic % to about 3 atomic %.

Sputtering deposition generally involves ejecting material from a target, which is the material source, and depositing the ejected material onto the substrate to form the film. DC sputtering generally involves applying a direct current to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. Other inert gases (e.g., argon, etc.) may also be present. The pressure of the reactive atmosphere can be between about 1 mTorr and about 20 mTorr for magnetron sputtering. The pressure can be even higher for diode sputtering (e.g., from about 25 mTorr to about 100 mTorr). When metal atoms are released from the target upon application of the voltage, the metal atoms deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps.

Conversely, RF sputtering involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) which may or may not contain reactive species (e.g., oxygen, nitrogen, etc.) having a pressure between about 1 mTorr and about 20 mTorr for magnetron sputtering. Again, the pressure can be even higher for diode sputtering (e.g., from about 25 mTorr to about 100 mTorr).

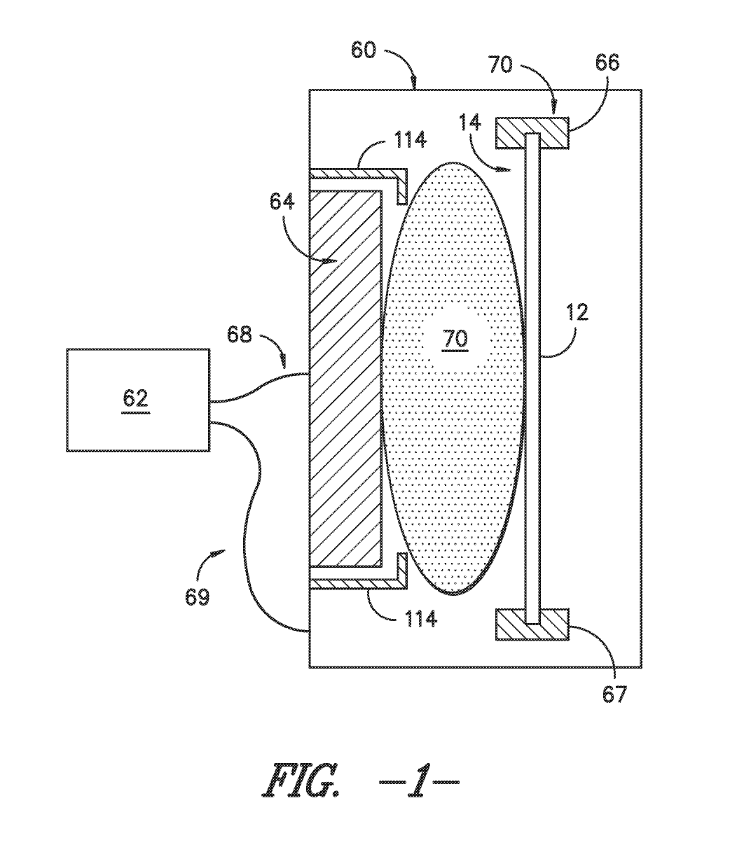

FIG. 1 shows a general schematic as a cross-sectional view of an exemplary DC sputtering chamber 60 according to one embodiment of the present invention. Although described as forming a RTB layer on the substrate 12, it is to be understood that any thin film layer can be formed using such apparatus and methods.

A DC power source 62 is configured to control and supply DC power to the chamber 60. As shown, the DC power source applies a voltage to the cathode 64 to create a voltage potential between the cathode 64 and an anode formed by the chamber wall, such that the substrate is in between the cathode and anode. The transparent substrate 12 is held between top support 66 and bottom support 67 (forming a conveyor system 70) via wires 68 and 69, respectively. Generally, the transparent substrate 12 is positioned within the sputtering chamber 60 such that the RTB layer is formed over the TCO layer 14 on the substrate 12 that faces the cathode 64.

A plasma field 70 is created once the sputtering atmosphere is ignited, and is sustained in response to the voltage potential between the cathode 64 and the chamber wall acting as an anode. The voltage potential causes the plasma ions within the plasma field 70 to accelerate toward the cathode 64, causing atoms from the cathode 64 to be ejected toward the surface on the transparent substrate 12. As such, the cathode 64 can be referred to as a “target” and acts as the source material for the formation of the RTB layer on the TCO layer 14 on the substrate 12 that faces the cathode 64. As stated, the cathode 64 can be a mixed metal target, such as elemental tin, cadmium, and/or zinc, or mixtures thereof.

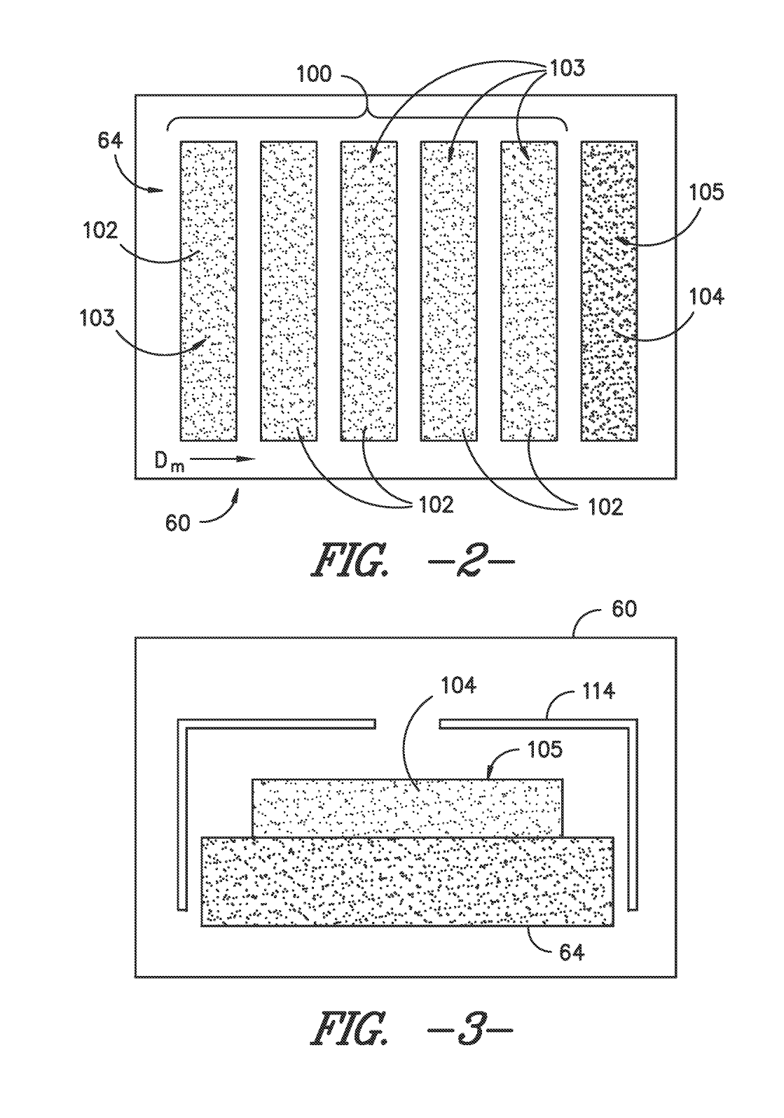

As shown more particularly in FIG. 2, in some embodiments, a plurality of cathodes 64 can be utilized. A plurality of cathodes 64 can be particularly useful to form a layer including several types of materials (e.g., co-sputtering). Since the sputtering atmosphere can contain oxygen gas, particularly when utilizing a metal target, oxygen particles of the plasma field 70 can react with the ejected target atoms to form a RTB layer on the TCO layer 14 on the substrate 12.

FIG. 2 shows one embodiment of a sputtering chamber 60, which can be utilized in the chamber 60 shown in FIG. 1, that includes a plurality 100 of first sputtering targets 102 and a second sputtering target 104 to make up the cathode 64. Each first sputtering target 100 includes a source material (e.g., zinc, tin, oxygen, etc., or mixtures thereof) that is the primary material to be included in the resulting thin film layer. Thus, the sputtering targets 102, 104 can be mixed metal targets (e.g., substantially free from oxygen) or ceramic targets (e.g., that include at least one metal oxide, such as a zinc tin oxide). As such, in one embodiment, each of the first sputtering targets 102 is substantially free from any dopant and/or other composition not included in the source material. As used herein, the term “substantially free” means no more than an insignificant trace amount present and encompasses completely free (e.g., 0 ppb up to 0.1 ppm).

Conversely, the second sputtering target 104 includes the source material and a dopant. Utilizing a mixture of the first sputtering targets 102 and second sputtering targets allows for more precise control of the concentration of the dopant in the system, and thus the concentration of the dopant deposited in the thin film. For example, in the embodiment shown in FIG. 2, more first sputtering targets 102 are present than second sputtering targets 104 in the sputtering chamber 60, allowing the amount of dopant in the system that is eventually deposited onto the thin film layer to be selectively controlled even at extremely low concentrations (e.g., less than about 500 ppm, such as about 1 ppm to about 100 ppm). In one particular embodiment, the amount of dopant in the system that is eventually deposited onto the thin film layer is about 1 ppm to about 20 ppm, such as about 5 ppm to about 15 ppm.

The conveyor system 70 is configured to transport each substrate 12 in the machine direction (Dₘ) past each of the first sputtering targets 102 and the second sputtering target 104 individually. Thus, the sputtering surfaces 103 and 105 of each first sputtering target 102 and the second sputtering target 104, respectively, faces the deposition surface 14 (formed, in this particular embodiment, by the TCO layer 14) of the substrate 12 during sputtering deposition. Thus, the thin film formed can be substantially uniform across the surface 14 of the substrate 12, though variations may exist through the thickness of the resulting thin film layer as the layer is deposited.

In one particular embodiment, a target shield 114 can be included within the sputtering chamber 60 to extend over a portion of the sputtering surface 103 of the first targets 102 and/or the sputtering surface 105 of the second sputtering target 104. Thus, the amount of material that is exposed to the plasma 70 can be controlled to further control the amount of dopant in the resulting deposited thin film layer.

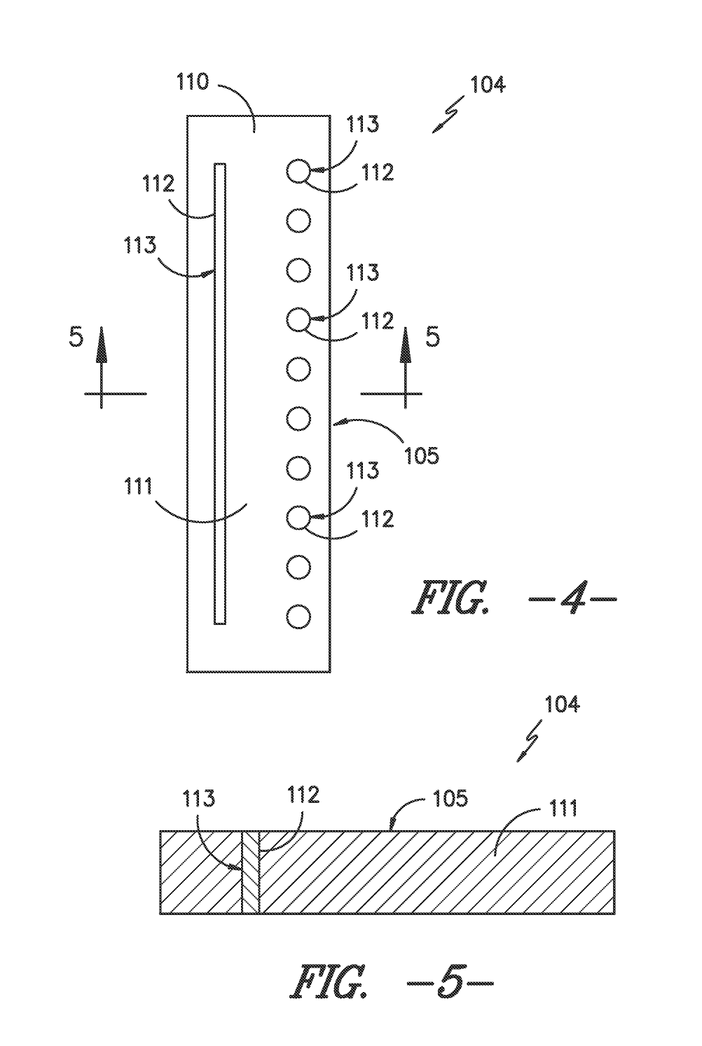

For example, referring to FIG. 3, the target shield 114 can perimetrically surround the target 104. In certain embodiments, the target shield 114 can extend over at least about 10% to about 75% of the sputtering surface 105 (e.g., about 25% to about 75%) to cause less atoms to be ejected from the second sputtering target 104 than each of the first sputtering targets 102. Thus, the amount of material that is exposed to the plasma 70 can be minimized from the second sputtering target 104 to further control the amount of dopant in the resulting deposited thin film layer.

Likewise, the target shield 104 can also extend over a portion of the first sputtering targets 102, though may cover less of their sputtering surfaces 103. For example, the target shield 104 can extend over about 1% to about 25% of the first sputtering surface of each first sputtering target (e.g., about 1% to about 10%).

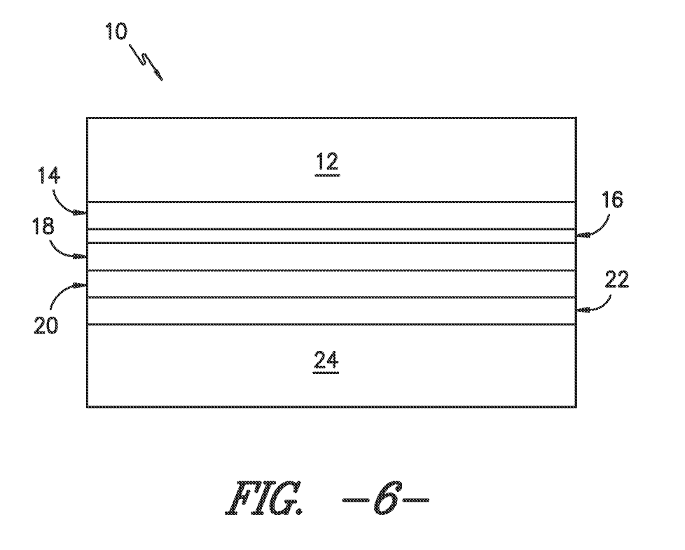

In one particular embodiment, the second sputtering target 104 can be formed by pressing a source material to form the sputtering target, forming an aperture within the sputtering target, and filling the aperture with the dopant. Referring to FIGS. 4 and 5, one particular embodiment of a second sputtering target 104 is shown formed via such a method. The second sputtering target 104 includes a pressed source material 111 defining apertures 113. A dopant 112 fills the apertures 113 within the source material 111 so that the second sputtering target 104 includes both the source material 111 and the dopant 112. In such an embodiment, the amount of dopant 112 within the target 104 can be specifically controlled, especially with respect to the relative amount of pressed source material 111 also present. Thus, the ratio of the dopant 112 to the source material 111 can be precisely controlled in the target 114 and the resulting thin film layer.

Referring back to FIG. 1, the sputtering chamber 60 is connected to a DC power source 62 to provide power to the targets 102 and 104. Although only a single DC power source 62 is shown, the voltage potential can be realized through the use of multiple power sources coupled together. Additionally, the exemplary sputtering chamber 60 is shown having a vertical orientation, although any other configuration can be utilized.

In one particular embodiment, the power source 62 is individually connected to each of the first sputtering targets 102 and to the second sputtering target 104, such as through the use of individual power supplies 63 shown in FIG. 7. As shown, each of the first sputtering targets 102 is electrically connected to an individual power supply 63a-63e via the respective electrical connections 68a, 69a-68e, 69e, and the second sputtering target 104 is electrically connected to an individual power supply 63f via the respective electrical connection 68f, 69f. This particular configuration allows for the amount of power directed to each of the targets 102, 103 from the power source 62 (composed of all of the individual power supplies 63a-63f, whether they are electrically tethered together or not) to be selectively controlled as desired. As such, the power supply 62 can be configured to provide a first power level to each of the first sputtering targets 102 and a second power level to the second sputtering target 104. The second power level can thus be adjusted to further control the sputtering rate of the second sputtering target 104, especially with respect to the sputtering rate of the first sputtering targets 102. In one embodiment, the second power level is less than the first power level such that the sputtering rate of the second sputtering target 104 is less than the sputtering rate of the first sputtering targets 102.

The presently provided methods of sputtering a RTB layer can be utilized in the formation of any film stack that utilizes a RTB layer, particularly those including a TCO layer formed from cadmium stannate and/or an n-type window layer formed from cadmium sulfide. For example, the RTB layer can be used during the formation of any cadmium telluride device that utilizes a cadmium telluride layer, such as in the cadmium telluride thin film photovoltaic device disclosed in U.S. Publication No. 2009/0194165 of Murphy, et al. titled “Ultra-high Current Density Cadmium Telluride Photovoltaic Modules.”

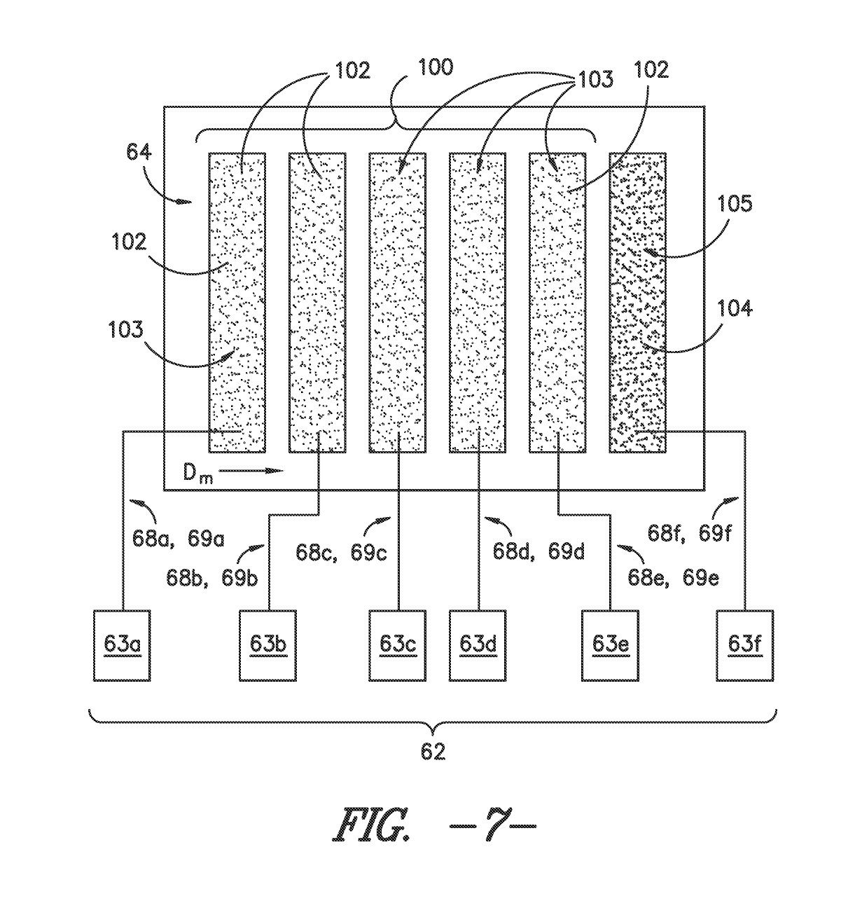

FIG. 6 represents an exemplary cadmium telluride thin film photovoltaic device 10 that can be formed according to methods described herein. The exemplary device 10 of FIG. 6 includes a top sheet of transparent substrate 12 employed as the substrate. In this embodiment, the transparent substrate 12 can be referred to as a “superstrate,” as it is the substrate on which the subsequent layers are formed even though it faces upward to the radiation source (e.g., the sun) when the cadmium telluride thin film photovoltaic device 10 is in use. The transparent substrate 12 can be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers. In one embodiment, the transparent substrate 12 can be a low iron float glass containing less than about 0.015% by weight iron (Fe), and may have a transmissivity of about 0.9 or greater in the spectrum of interest (e.g., wavelengths from about 300 nm to about 900 nm). In another embodiment, borosilicate glass may be utilized so as to better withstand high temperature processing. For example, a borosilicate glass can have a thickness of about 0.5 mm to about 2.5 mm.

The transparent conductive oxide (TCO) layer 14 is shown on the transparent substrate 12 of the exemplary device 10 of FIG. 6. The TCO layer 14 allows light to pass through with minimal absorption while also allowing electric current produced by the device 10 to travel sideways to opaque metal conductors (not shown). For instance, the TCO layer 14 can have a sheet resistance less than about 30 ohm per square, such as from about 4 ohm per square to about 20 ohm per square (e.g., from about 8 ohm per square to about 15 ohm per square). In certain embodiments, the TCO layer 14 can have a thickness between about 0.1 μm and about 1 μm, for example from about 0.1 μm to about 0.5 μm, such as from about 0.25 lam to about 0.35 μm.

The resistive transparent buffer layer 16 (RTB layer) is shown on the TCO layer 14 on the exemplary cadmium telluride thin film photovoltaic device 10. The RTB layer 16 is generally more resistive than the TCO layer 14 and can help protect the device 10 from chemical interactions between the TCO layer 14 and the subsequent layers during processing of the device 10. For example, in certain embodiments, the RTB layer 16 can have a sheet resistance that is greater than about 1000 ohms per square, such as from about 10 kOhms per square to about 1000 MOhms per square. The RTB layer 16 can also have a wide optical bandgap (e.g., greater than about 2.5 eV, such as from about 2.7 eV to about 3.0 eV).

Without wishing to be bound by a particular theory, it is believed that the presence of the RTB layer 16 between the TCO layer 14 and the cadmium sulfide layer 18 can allow for a relatively thin cadmium sulfide layer 18 to be included in the device 10 by reducing the possibility of interface defects (i.e., “pinholes” in the cadmium sulfide layer 18) creating shunts between the TCO layer 14 and the cadmium telluride layer 20. Thus, it is believed that the RTB layer 16 allows for improved adhesion and/or interaction between the TCO layer 14 and the cadmium telluride layer 20, thereby allowing a relatively thin cadmium sulfide layer 18 to be formed thereon without significant adverse effects that would otherwise result from such a relatively thin cadmium sulfide layer 18 formed directly on the TCO layer 14.

The RTB layer 16 is described in greater detail above, and can include, for instance, a copper doped tin oxide (SnO₂) and optionally zinc oxide, which can be referred to as a copper doped zinc tin oxide layer (“Cu:ZTO”). In one particular embodiment, the RTB layer 16 can include more tin oxide than zinc oxide. For example, the RTB layer 16 can have a composition with a stoichiometric ratio of ZnO/SnO₂ between about 0.25 and about 3, such as in about an one to two (1:2) stoichiometric ratio of tin oxide to zinc oxide. As stated, the RTB layer 16 can be formed by sputtering, chemical vapor deposition, spraying pyrolysis, or any other suitable deposition method. In one particular embodiment, the RTB layer 16 can be formed by sputtering (e.g. DC sputtering or RF sputtering) on the TCO layer 14 (as discussed below in greater detail above).

In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 lam and about 0.2 μm, for example from about 0.1 μm to about 0.15 μm.

An n-type window layer 18 is shown on RTB layer 16 of the exemplary device 10 of FIG. 6. In one embodiment, the n-type window layer 18 can generally include cadmium sulfide but may also include other materials, such as zinc sulfide, cadmium zinc sulfide, etc., and mixtures thereof as well as dopants and other impurities (i.e., forming a cadmium sulfide layer). In this embodiment, the cadmium sulfide layer may include oxygen up to about 25% by atomic percentage, for example from about 5% to about 20% by atomic percentage. Such a cadmium sulfide layer can have a wide band gap (e.g., from about 2.25 eV to about 2.5 eV, such as about 2.4 eV) in order to allow most radiation energy (e.g., solar radiation) to pass. As such, the cadmium sulfide layer 18 is considered a transparent layer on the device 10.

The cadmium sulfide layer 18 can be formed by sputtering, chemical vapor deposition, chemical bath deposition, and other suitable deposition methods. In one particular embodiment, the cadmium sulfide layer 18 can be formed by sputtering (e.g., direct current (DC) sputtering or radio frequency (RF) sputtering) on the resistive transparent buffer layer 16.

Due to the presence of the resistive transparent buffer layer 16, the n-type window layer 18 can have a thickness that is less than about 0.1 μm, such as between about 10 nm and about 100 nm, such as from about 50 nm to about 80 nm, with a minimal presence of pinholes between the resistive transparent buffer layer 16 and the n-type window layer 18. Additionally, a n-type window layer 18 having a thickness less than about 0.1 μm reduces any absorption of radiation energy by the n-type window layer 18, effectively increasing the amount of radiation energy reaching the underlying absorber layer 20.

An absorption layer 20 is shown on the n-type window layer 18 in the exemplary thin film photovoltaic device 10 of FIG. 6. The absorber layer 20 is a p-type layer that interacts with the n-type window layer 18 (e.g., the cadmium sulfide layer) to produce current from the absorption of radiation energy by absorbing the majority of the radiation energy passing into the device 10 due to its high absorption coefficient and creating electron-hole pairs. In one particular embodiment, the absorber layer can include cadmium telluride (i.e., a cadmium telluride layer); however, other materials can include, but are not limited to, (Ag,Cu)(In,Ga)(Se,S)₂, (Ag,Cu)ZnSn(Se,S), GaAs, amorphous Si, or other absorber materials.

For example, when the absorber layer 20 is formed from cadmium telluride, the resulting cadmium telluride layer 20 can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 20) across the junction to the n-type side (i.e., the cadmium sulfide layer 18) and, conversely, holes may pass from the n-type side to the p-type side. Thus, the p-n junction formed between the cadmium sulfide layer 18 and the cadmium telluride layer 20 forms a diode in which the charge imbalance leads to the creation of an electric field spanning the p-n junction. Conventional current is allowed to flow in only one direction and separates the light induced electron-hole pairs.

The absorber layer 20 can be formed by any known process, such as vapor transport deposition, chemical vapor deposition (CVD), spray pyrolysis, electro-deposition, sputtering, close-space sublimation (CSS), etc. In one particular embodiment, the n-type window layer 18 is deposited by a sputtering and the absorber layer 20 is deposited by close-space sublimation. In particular embodiments, the absorber layer 20 can have a thickness between about 0.1 μm and about 10 μm, such as from about 1 μm and about 5 μm. In one particular embodiment, the absorber layer 20 can have a thickness between about 2 μm and about 4 μm, such as about 3 μm.

A series of post-forming treatments can be applied to the exposed surface of the absorber layer 20. These treatments can tailor the functionality of the absorber layer 20 and prepare its surface for subsequent adhesion to the back contact layer(s) 22. For example, when formed from cadmium telluride, the absorber layer 20 can be annealed at elevated temperatures (e.g., from about 350° C. to about 500° C., such as from about 375° C. to about 424° C.) for a sufficient time (e.g., from about 1 to about 10 minutes) to create a quality p-type layer of cadmium telluride. Without wishing to be bound by theory, it is believed that annealing the cadmium telluride layer 20 (and the device 10) converts the normally lightly p-type doped, or even n-type doped cadmium telluride layer 20 to a more strongly p-type cadmium telluride layer 20 having a relatively low resistivity. Additionally, the cadmium telluride layer 20 can recrystallize and undergo grain growth during annealing.

Annealing the cadmium telluride layer 20 can be carried out in the presence of cadmium chloride in order to dope the cadmium telluride layer 20 with chloride ions. For example, the cadmium telluride layer 20 can be washed with an aqueous solution containing cadmium chloride and then annealed at the elevated temperature.

In one particular embodiment, after annealing the cadmium telluride layer 20 in the presence of cadmium chloride, the surface can be washed to remove any cadmium oxide formed on the surface. This surface preparation can leave a Te-rich surface on the cadmium telluride layer 20 by removing oxides from the surface, such as CdO, CdTeO₃, CdTe₂O₅, etc. For instance, the surface can be washed with a suitable solvent (e.g., ethylenediamine also known as 1,2 diaminoethane or “DAE”) to remove any cadmium oxide from the surface.

Additionally, copper can be added to the cadmium telluride layer 20. Along with a suitable etch, the addition of copper to the cadmium telluride layer 20 can form a surface of copper-telluride on the cadmium telluride layer 20 in order to obtain a low-resistance electrical contact between the cadmium telluride layer 20 (i.e., the p-type layer) and the back contact layer(s). Specifically, the addition of copper can create a surface layer of cuprous telluride (Cu₂Te) between the cadmium telluride layer 20 and the back contact layer 22. Thus, the Te-rich surface of the cadmium telluride layer 20 can enhance the collection of current created by the device through lower resistivity between the cadmium telluride layer 20 and the back contact layer 22.

Copper can be applied to the exposed surface of the cadmium telluride layer 20 by any process. For example, copper can be sprayed or washed on the surface of the cadmium telluride layer 20 in a solution with a suitable solvent (e.g., methanol, water, or the like, or combinations thereof) followed by annealing. In particular embodiments, the copper may be supplied in the solution in the form of copper chloride, copper iodide, or copper acetate. The annealing temperature is sufficient to allow diffusion of the copper ions into the cadmium telluride layer 20, such as from about 125° C. to about 300° C. (e.g. from about 150° C. to about 200° C.) for about 5 minutes to about 30 minutes, such as from about 10 to about 25 minutes.

A back contact layer 22 is shown on the cadmium telluride layer 20. The back contact layer 22 generally serves as the back electrical contact, in relation to the opposite, TCO layer 14 serving as the front electrical contact. The back contact layer 22 can be formed on, and in one embodiment is in direct contact with, the cadmium telluride layer 20. The back contact layer 22 is suitably made from one or more highly conductive materials, such as elemental nickel, chromium, copper, tin, aluminum, gold, silver, technetium or alloys or mixtures thereof. Additionally, the back contact layer 22 can be a single layer or can be a plurality of layers. In one particular embodiment, the back contact layer 22 can include graphite, such as a layer of carbon deposited on the p-layer followed by one or more layers of metal, such as the metals described above. The back contact layer 22, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 22, can be from about 0.1 μm to about 1.5 μm in thickness.

The encapsulating substrate 24 is also shown in the exemplary cadmium telluride thin film photovoltaic device 10 of FIG. 6.

Other components (not shown) can be included in the exemplary device 10, such as bus bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells.

Although not specifically shown in FIG. 6, other thin film layers may also be present in the thin film stack. For example, index matching layers can be positioned between the transparent conductive oxide layer 14 and the transparent substrate 12. Additionally, an oxygen getter layer (e.g., comprising alumina) can be positioned between the transparent conductive oxide layer 14 and the resistive transparent buffer layer 16.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A sputtering chamber, comprising:
a first sputtering target within the sputtering chamber, wherein the first sputtering target comprises a source material;
a second sputtering target within the sputtering chamber, wherein the second sputtering target comprises the source material and a dopant;
a power source electrically connected to the sputtering chamber and to each of the first sputtering targets and the second sputtering target; and,
a conveyor system configured to transport a plurality of substrates through the sputtering chamber to deposit a thin film onto a surface of each substrate.

2. The sputtering chamber as in claim 1, wherein a plurality of the first sputtering targets are within the sputtering chamber.

3. The sputtering chamber as in claim 2, wherein each of the first sputtering targets is substantially free from the dopant.

4. The sputtering chamber as in claim 2, wherein the power supply is individually connected to each of the first sputtering targets and the second sputtering target.

5. The sputtering chamber as in claim 4, wherein the power source comprises a plurality of power supplies, and wherein a power supply is individually connected to each of the first sputtering targets and the second sputtering target.

6. The sputtering chamber as in claim 2, wherein the power supply is configured to provide a first power level to each of the first sputtering targets and a second power level to the second sputtering target, and wherein the second power level is less than the first power level.

7. The sputtering chamber as in claim 2, a target shield positioned between a portion of each of the first sputtering targets and the conveyor system, wherein the target shield extends over at least a portion of each of the first sputtering targets.

8. The sputtering chamber as in claim 7, wherein each of the first sputtering targets define a first sputtering surface, and wherein the target shield extends over about 1% to about 25% of the first sputtering surface of each first sputtering target.

9. The sputtering chamber as in claim 1, further comprising:
a target shield positioned between a portion of the second sputtering target and the conveyor system, wherein the target shield extends over at least a portion of the second sputtering target.

10. The sputtering chamber as in claim 9, wherein the second sputtering target defines a second sputtering surface, and wherein the target shield extends over about 25% to about 75% of the second sputtering target.

11. The sputtering chamber as in claim 1, wherein the dopant is present within the second sputtering target as a discrete insert within a cavity defined by the source material.

12. The sputtering chamber as in claim 1, wherein the conveyor system is configured to transport a plurality of substrates past each of the first sputtering targets and the second sputtering target individually.

13. A method of making a sputtering target, comprising:
pressing a source material to form the sputtering target;
forming an aperture within the sputtering target; and,
filling the aperture with a dopant.

14. A sputtering target defining a sputtering surface, the sputtering target comprising: a source material and a dopant, wherein the source material defines a cavity extending in a direction perpendicular to the sputtering surface of the sputtering target, and wherein the dopant is present within the cavity.

15. The sputtering target as in claim 14, wherein the sputtering target defines a length that is perpendicular to the sputtering surface defined by the sputtering target, and wherein the cavity defines a slot extending across about 75% or more of the length of the sputtering target.

16. The sputtering target as in claim 14, wherein the sputtering target defines a plurality of cavities within the sputtering target, each cavity extending perpendicular to the sputtering surface, and wherein the dopant is present within each cavity.

17. The sputtering target as in claim 14, wherein the source material comprises zinc and tin.

18. The sputtering target as in claim 14, wherein the dopant comprises copper.
